(19) United States
(12) Patent Application Publication
(10) Pub. No.: US 2003/0204796 A1
(43) Pub. Date: Oct. 30, 2003

(54) Serial input/output testing method

(76) Inventors: Wen-Hsi Lin, Hsinchu (TW); Hsin-Chiang Huang, Hsinchu (TW)

Correspondence Address: STOUT, UXA, BUYAN & MULLINS LLP, 4 VENTURE, SUITE 300, IRVINE, CA, 92618, US

(21) Appl. No.: 10/128,895

(22) Filed: Apr. 24, 2002

(51) Int. Cl. G11C 29/00

(52) U.S. Cl. 714/718

(57) ABSTRACT

A serial I/O testing method is performed by a testing system for testing a memory device having a first pin, a second pin, and a third pin. The testing method includes a step of inputting a clock into the memory device through the first pin, followed by a step of inputting a serial address into the memory device through the second pin synchronized with the clock. The method further includes a step of inputting a command into the memory device and a step of, when the command is a read command, outputting from the third pin a serially-written data synchronized with the clock. When the command is a program command, the method includes inputting an initial data serially through the third pin synchronized with the clock, and programming the initial data into the memory device before outputting it on the third pin as programmed data from the memory device synchronized with the clock. The serially-written data, in the case of read command, or the programmed data, in the case of a program command, is then compared with an original or expected data.

### BACKGROUND OF THE INVENTION

1. Field of the Invention

The present invention relates generally to the testing of memory devices and, more particularly, to methods and apparatuses for increasing the speed of testing memory devices.

2. Description of Related Art

In the era of very large scale integrated (VLSI) circuits, the trend in the fabrication of memory chips has been to construct increasingly larger memory arrays onto constant or smaller sized die (semiconductor chips). Unfortunately, the difficulty of testing the memory devices increases as the number of elements on a chip grows, requiring greater amounts of resources and time.

The fabrication of today's dense VLSI memory arrays dictates that a significant portion of the manufacturing process be spent testing the memory arrays. In response, tester manufacturers have created automated testing systems that simultaneously test multiple memory devices. Tests can be performed on the memory device after fabrication while still on the silicon wafer, after being packaged as a chip, or at both times. It may be easier to design automatic testers for use on packaged chips, but if the die is tested early on then overhead cost can be reduced by discarding defective memory devices before additional resources are spent on them.

Memory testers used on multiple memory devices typically introduce tests on the memory devices and compare outputs from the memory devices with standard or expected values.

Robotic machinery can be used to places memory chips on a test board, and to initiate electrical contact between the memory devices and the external circuitry of the memory tester. A memory tester's external circuitry is typically designed in terms of modules, with each module corresponding to a terminal of the memory device. During a test, each separate module can function in one of three modes; namely, each module can send data, receive data, or remain idle.

Tests are executed by the exchange of signals between the memory tester and the memory device or devices. To test a memory device, address signals can be generated and fed from the tester to the memory device's input address pins, and subsequently test data input signals can be fed to the memory device's input data pins. The data input signals, once applied to the memory device, are routed to respective memory segments within the memory device before an output is advanced from the memory device. This output, when compared to a standard by the memory tester, indicates whether a selected memory segment of the memory device is operating properly. When the test fails a logical value of 1 can be output and stored in a failure analysis memory, indexed with the corresponding address signal. This failure analysis memory stores only failed memory blocks, and passing blocks are ignored.

A common practice is to utilize a parallel input/output (I/O) memory tester in which output signals from the memory device under test can be inspected after a defined series of signals have been sent from the tester to the memory device. The parallel I/O tester then reads the memory, and the output is compared to a predetermined standard. If the values compare or match, then the memory elements are deemed to be operating satisfactorily.

Parallel I/O testers are typically configured to have several modes of operation. A first mode of operation is a “read” mode in which data issued (read) from the memory device is received by the parallel I/O tester and compared to a standard. The second mode is a “write” mode in which values are written into the memory device, and subsequently read back and compared to a standard. As an example, a logical value (1 or 0) is written into all of the memory cells of a memory device by the parallel I/O tester. Subsequently, each memory bit is read back by the parallel I/O tester in order to establish whether or not the memory contents correspond to previously determined standards. A third testing mode is an “erase” mode, wherein the contents of a memory cell are erased and then read by the parallel I/O tester to thereby ensure that the contents were properly erased.

When a parallel I/O tester is used, the number of probes required to test a memory device will typically increases as the capacity of the memory device is augmented. This phenomenon is due to the fact that the number of address bits and the number of I/O bits have both increased, and thus the number of pins has also increased. As the amount of pins required to test a single memory device increases, a fewer number of devices can be simultaneously tested by a parallel I/O tester having the same number of pins. For example, when using a conventional parallel I/O tester to test a memory device, if the memory device has forty-two I/O pins including twenty-three input pins, sixteen output pins, a chip-enable pin, an output-enable pin, and a write enable pin, then the parallel I/O tester must contain forty-two or more probes so as to test the memory device.

A greater number of pins can be provided on the parallel I/O tester to facilitate the testing of multiple memory devices at once, but this construction will increase costs. It would be desirable to decrease the number of pins required to test each memory device, while still facilitating the testing of multiple memory devices at once, to thereby reduce costs. Moreover, it would be desirable to decrease the testing time required for each memory device, without having to increase associated costs. Thus, there remains a need in the prior art for speedily and effectively testing semiconductor devices, and there further remains a need in the prior art for containing the costs associated with conventional memory testing devices.

### SUMMARY OF THE INVENTION

The present invention seeks to meet these needs by providing, in accordance with one aspect, methods of testing memory devices using serial communications between the testing system and the memory device being tested. The serial communications comprise inputs and outputs between the testing system and the memory device, and the serial communications are executed in synchronization with a clock signal. Consequently, fewer pins are needed to test each memory device and the complexity (e.g., number of testing probes) of the testing system can be commensurately reduced. This reduction in the complexity of the testing system, per memory device being tested, can allow the testing system to simultaneously test a greater number of memory devices at once.

To achieve these and other advantages and in accordance with a purpose of the invention, as embodied and broadly described herein, the invention provides a serial I/O testing method performed in a testing system for testing a memory device. The method comprises a step of inputting a timing signal from the testing system into the memory device, which is followed by a step of inputting an address serially into the memory device, wherein the address is inputted into the memory device from the testing system in synchronization with the timing is signal. A memory location of the memory device is then accessed using the address, and data is serially outputted from that memory location in synchronization with the timing signal.

In one implementation of the invention, a command is inputted into the memory device to specify whether a read or a program operation is to be performed by the memory device. In another implementation, the command further specifies whether an erase procedure is to be performed by the memory device. When the command is a read command, the accessing step and the outputting step are performed, the data outputted in the outputting step comprises serially-written data, and the method further comprises a step of comparing the serially-written data and an original data. On the other hand, when the command is a program command, the accessing step is proceeded by a step of serially inputting initial data into the memory device in synchronization with the timing signal and a step of programming the initial data into the memory location of the memory device, and the method further comprises a step of comparing the outputted data and an original data.

In accordance with another aspect of the present invention, a serial I/O testing method is performed by a testing system for testing a memory device, wherein the memory device has a first pin and at least one additional pin. The testing method comprises a step of inputting a clock into the memory device through the first pin, followed by a step of inputting a serial address into the memory device through the at least one additional pin, wherein the serial address is inputted synchronized with the clock. The method continues with a step of inputting a command into the memory device and a step of, when the command is a read command, outputting from the at least one additional pin synchronized with the clock a serially-written data, wherein the serially-written data corresponds to serially-written data stored in the memory device. The method further comprises a step of comparing the serially-written data and an original data, when the read command has been inputted into the memory device. In one implementation, the command pin is inputted through the at least one additional pin. In another implementation, the at least one additional pin comprises a second pin and a third pin, wherein the serial address is inputted through the second pin and the serially-written data is outputted through the third pin.

When the command is a program command, the testing method can comprise a step of serially inputting an initial data through the third pin, wherein the initial data is synchronized with the clock, followed by another step of programming the initial data into the memory device and a step of outputting the programmed initial data in serial from the memory device through the third pin, wherein the programmed initial data is outputted synchronized with the clock. The programmed data can then be compared with an original data.

The memory can further comprise a fourth pin, a fifth pin, and a sixth pin, and the method can further comprise the steps of inputting a chip-enable signal to the memory device through the fourth pin, inputting an output-enable signal to the memory device through the fifth pin, and inputting a write-enable signal to the memory device through the sixth pin.

In each of the foregoing aspects, the present invention provides a method of testing at least one memory device using serial input and output communications with the memory device, wherein the communications are synchronized with a clock supplied to the memory device.

Any feature or combination of features described herein are included within the scope of the present invention provided that the features included in any such combination are not mutually inconsistent as will be apparent from the context, this specification, and the knowledge of one of ordinary skill in the art.

Additional advantages and aspects of the present invention are apparent in the following detailed description and claims. It is to be understood that both the foregoing general description and the following detailed description are exemplary, and are intended to provide further explanation of the invention as claimed.

### BRIEF DESCRIPTION OF THE DRAWINGS

FIG. 1 is a block diagram illustrating a memory device connected to a parallel I/O testing system in accordance with the prior art;

FIG. 2 is a schematic diagram illustrating a serial I/O testing system connected to a memory device integrated circuit on a semiconductor wafer in accordance with an embodiment of the present invention;

FIGS. 3a and 3b are block diagrams illustrating serial I/O testing systems connected to packaged memory devices in accordance with two embodiments of the present invention;

FIG. 4 illustrates functional components of a dynamic random access memory device to which the serial I/O testing system of the present invention may be connected for testing;

FIG. 5 illustrates functional components of the serial I/O testing system in accordance with one embodiment of the present invention;

FIG. 6 is a flow chart representing steps for testing a single memory device in accordance with an embodiment of the present invention;

FIG. 7 is a diagram showing a timing sequence for a “read” command test of a single memory device as implemented by a serial I/O testing system in accordance with the present invention;

FIG. 8 is a diagram showing a timing sequence for a “program” command test of a single memory device as implemented by a serial I/O testing system in accordance with the present invention;

FIG. 9 is a schematic diagram illustrating a serial I/O testing system connected to a plurality of memory device integrated circuits on a semiconductor wafer in accordance with an embodiment of the present invention;

FIG. 10 is a block diagram illustrating a serial I/O testing system connected to a plurality of packaged memory devices in accordance with an embodiment of the present invention;

FIG. 11 is a flow chart representing steps for testing a plurality of memory devices in accordance with an embodiment of the present invention;

FIG. 12 is a diagram showing timing sequences for “read” command tests of a plurality of memory devices as implemented by a serial I/O testing system in accordance with the present invention; and

FIG. 13 is a diagram showing timing sequences for “program” command tests of a plurality of memory devices as implemented by a serial I/O testing system in accordance with the present invention.

### DETAILED DESCRIPTION OF THE PRESENTLY PREFERRED EMBODIMENTS

Reference will now be made in detail to the presently preferred embodiments of the invention, examples of which are illustrated in the accompanying drawings. Wherever possible, the same reference numbers are used in the drawings and the description to refer to the same or like parts. It should be noted that the drawings are in greatly simplified form, are not inclusive, and are not to precise scale. In reference to the disclosure herein, for purposes of convenience and clarity only, directional terms, such as, top, bottom, left, right, up, down, above, below, beneath, rear, and front, may be used with respect to the accompanying drawings. Such directional terms should not be construed to limit the scope of the invention in any manner.

Although the disclosure herein refers to certain illustrated embodiments, it is understood that these embodiments are presented by way of example and not by way of limitation. The intent of the following detailed description is to cover all modifications, alternatives, and equivalents as may fall within the spirit and scope of the invention as defined by the appended claims. It is to be understood and appreciated that the process steps and structures described herein do not cover a complete process flow for the manufacture, operation, and testing of memory devices and memory testing systems. The present invention can be practiced in conjunction with various integrated circuit memory testing devices and techniques that are used in the art, and only so much of the commonly practiced structures and process steps are included herein as are necessary to provide an understanding of the present invention.

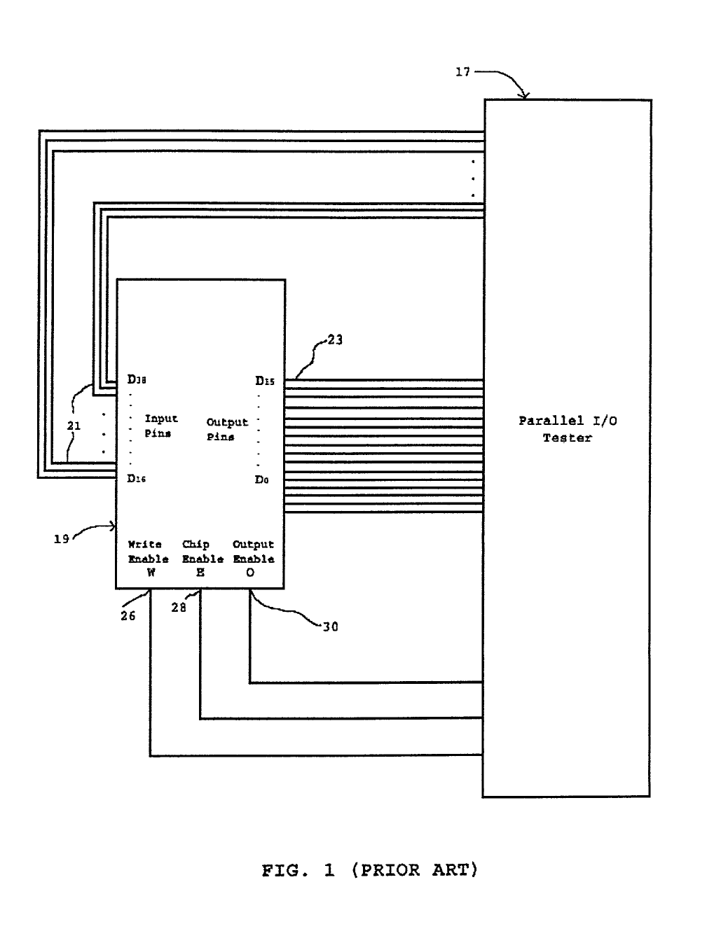

Referring more particularly to the drawings, FIG. 1 illustrates a conventional parallel I/O tester 17 connected to a memory device 19 for testing thereof. The parallel I/O tester 17 comprises probes or other devices that are connected to a corresponding plurality of I/O pins of the memory device 19. In the illustrated configuration of FIG. 1, the memory device 19 comprises forty-two I/O pins, which include sixteen output pins D0-D15, twenty-three input pins D16-D38, a write-enable pin W, a chip-enable pin E and an output-enable pin O. The memory device 19 will typically comprise additional pins such as, for example, a power pin.

The parallel I/O tester 17 is connected to the input pins D16-D38 via conductors 21; is connected to the output pins D0-D15 via conductors 23; and is connected to the write-enable pin W, the chip-enable pin E, and the output-enable pin O via conductors 26, 28 and 30, respectively.

Signals such as addresses and data signals are communicated in a parallel fashion between the parallel I/O tester 17 and the memory device 19 via the conductors 21 and 23. As an example, for a “read” test the appropriate chip-enable pin E and output-enable pin O should be driven by the parallel I/O tester 17 via conductors 28 and 30, respectively. The parallel I/O tester 17 may initiate the read request by placing an address in parallel fashion on conductors 21. In response to the read request from the parallel I/O tester 17, the memory device 19 may output a sixteen bit data in parallel fashion on the sixteen output pins D0-D15. As a result of the above exemplary communication with the memory device 19, the parallel I/O tester 17 must be configured with a number of probes sufficient to interface with the forty-two I/O pins D0-D38, W, E and O of the memory device 19. More particularly, the parallel I/O tester 17 must be constructed to have forty-two or more probes in order to test the memory device 19. Such a relatively large number of probes for the testing of a single memory device can add to both the manufacturing time and cost of the memory device.

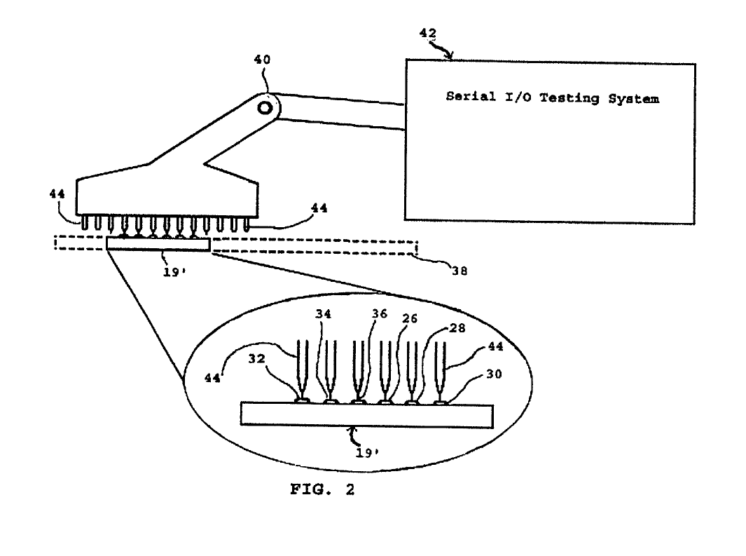

FIG. 2 is a schematic diagram illustrating a serial I/O testing system 42 according to the present invention connected to a memory device integrated circuit 19′ on a semiconductor wafer 38, such as a silicon wafer. A loading mechanism 40 extends from the serial I/O testing system 42, and comprises a plurality of probes 44 which are sized and configured to establish efficient contacts to pads (or pins) of the memory device 19′. Probes 44 of the loading mechanism 40 are shown establishing electrical connections with a first pad 32 and at least one additional pad. In the illustrated embodiment, this additional pad(s) comprises a second pad 34 and a third pad 36. The loading mechanism 40 is further shown establishing optional electrical connections with a fourth pad 26, a fifth pad 28 and a sixth pad 30 of the memory device 19′. All of the pads 32, 34, 36, 26, 28 and 30 of the FIG. 2 embodiment comprise contact points of a single die, which is still on the semiconductor wafer 38.

The probes 44 in turn are connected back to the serial I/O testing system 42. Thus, in the illustrated embodiment of FIG. 2, only six or fewer probes 44 are used to electrically connect the memory device 19′ to the serial I/O testing system 42 for testing, which number is sizably reduced compared to the forty-two connections required in the configuration of FIG. 1. Although six probes 44 are shown, the the number of probes 44 can be reduced to smaller numbers of probes, such as two probes comprising only a clock probe and an I/O probe.

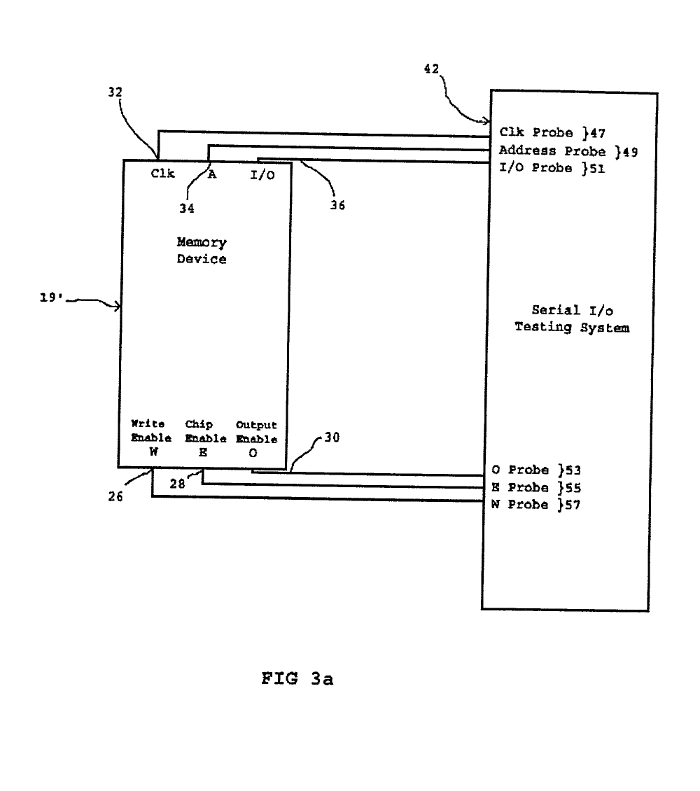

The memory device 19′ can be tested at two points during its manufacture. Namely, the memory device 19′ can be tested after it has been fabricated but while still on the silicon wafer as illustrated in FIG. 2, or after it has been packaged as illustrated for example in FIGS. 3a and 3b. The terms pin and pad are used interchangeably herein, since in the presently described embodiments the terms represent substantially the same electronic meaning, with the term “pad” being used while the memory device is still on a silicon wafer and the term “pin” being used after the memory device has been packaged. As presently embodied, the memory device 19′ may comprise a random-access memory (RAM), a static random access memory (SRAM), a dynamic random access memory (DRAM), a read only memory (ROM), a one-time programmable read only memory (OTP ROM), a multiple-time programmable read only memory (MTP ROM), an erasable programmable read-only memory (EPROM), an electrically erasable programmable read-only memory (EEPROM), a flash memory, or a similar structure.

FIG. 3a is a block diagram illustrating a serial I/O testing system 42 connected to a packaged memory device 19′ in accordance with another implementation of the present invention. As shown the memory device 19′ comprises pins which are connected to the serial I/O testing system 42 via conductors. In FIG. 3a the memory device 19′ has been packaged and is shown being tested in its final form as a chip by the serial I/O testing system 42. The memory device 19′ comprises a first pin 32 and at least one additional pin. In the illustrated embodiment, this additional pin(s) comprises a second pin 34 and a third pin 36. The memory device 19′ is further shown optionally comprising a fourth pin 26, a fifth pin 28 and a sixth pin 30. In the illustrated embodiment, the actual pins 32, 34, 36, 26, 28 and 30 are part of the I/O pins of the original memory device. Thus, the pins 32, 34, 36, 26, 28 and 30 may serve as conventional I/O pins of the memory device 19′, until a serial testing mode is initiated by the serial I/O testing system 42 at which time at least two, and in the illustrated embodiment all, of the pins 32, 34, 36, 26, 28 and 30 operate to facilitate testing by the serial I/O testing system 42. These pins 32, 34, 36, 26, 28 and 30 are shown connected to the serial I/O testing system 42 via an I/O probe 51, an address probe 49, a clock probe 47, a write-enable probe 57, a chip-enable probe 55 and an output-enable probe 53, respectively.

FIG. 3b illustrates an embodiment wherein the serial I/O testing system 42 comprises the clock probe 37 and one additional probe, which in the figure is a serial I/O probe 50. In this embodiment, the serial I/O probe 50 performs substantially the same functions as the combined functions of the address probe 49 and the I/O probe 51. The memory device 19′ of FIG. 3b comprises the first pin 32 and an additional pin 35, which in the illustrated embodiment performs substantially the same functions as a combination of the second pin 34 and the third pin 36.

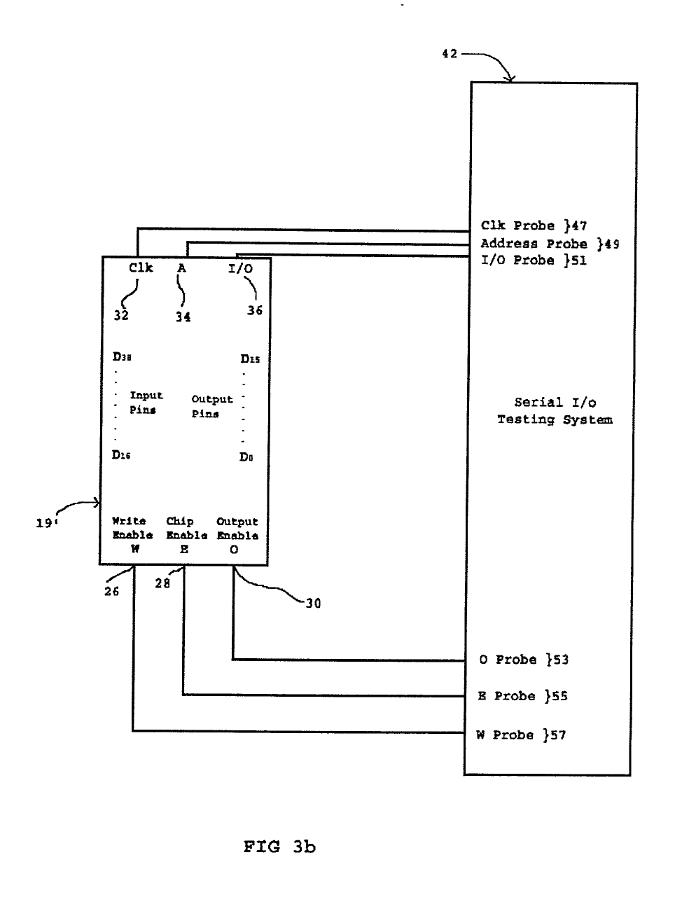

A simplified illustration of several functional components of a dynamic random access memory device 19″ to which the serial I/O testing system 42 of the present invention may be connected for testing is illustrated in FIG. 4. In the exemplary embodiment, the location of a memory address is divided into a row address and a column address as is well known in the art.

An address, which may comprise a row address and a column address, is applied from, for example, the address probe 49 of the serial I/O testing system 42 of FIGS. 3a to that which will be referred to herein as a serial I/O buffer 60 of the memory device 19″. The address from the address probe 49 is synchronized with a clock signal from the clock probe 47, and the clock signal 47 is received into the clock input 70 of the memory device 19″ for clock synchronization purposes of the memory device 19″ as discussed below. In the illustrated embodiment, the row address from the address supplied by the address probe 49 is decoded by the row decoder 68, which then activates a word line corresponding to the row address. The signal from the row decoder 68 may be amplified by an optional amplification circuit (not shown) before being routed through an I/O gate circuit 62 and to the serial I/O buffer 60. The column address is likewise decoded by a column decoder 64 and routed through the I/O gate circuit 62 to the serial I/O buffer 60. Thus, the contents of the address being tested are located within the memory device 19″ for subsequent outputting. The contents of the address in question are outputted by the serial I/O buffer 60, in serial and in synchronization with the clock signal inputted into the clock input 70, to the I/O probe 51 of the serial I/O testing device 42.

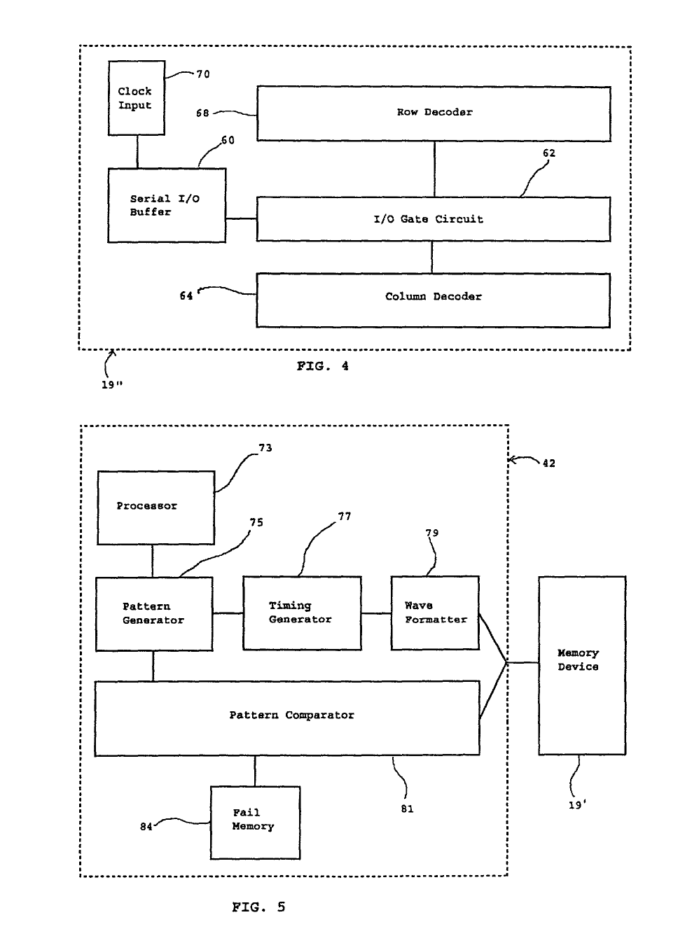

FIG. 5 illustrates functional components of the serial I/O testing system 42 in accordance with one exemplary embodiment of the present invention. The internal functional components of the serial I/O testing system 42 may be modified using circuit design and engineering principles known in the art, so long as, for example, the resulting serial I/O testing system 42 is able to test a memory device using serial addresses and serial I/O signals in synchronization with a timing signal. In the illustrated embodiment, the processor 73 is a dedicated processor for the operation of the serial I/O testing system 42. The processor 73 provides a pattern signal, which is sent to a pattern generator 75. The pattern generator 75 then adds timing data and waveform data and sends these items on to the timing generator 77 and wave formatter 79 in sequence. An output of the wave formatter 79 will be synchronized with the clock signal supplied to the memory device 19′ for certain data signals (e.g., addresses and initial data) that are to be communicated, in accordance with a predetermined pattern, to the memory device 19′ for testing.

Pattern, timing, and waveform data are also routed to the pattern comparator 81. The aforementioned testing data travels through the wave formatter 79 and into the memory device 19′. In a read example, a read sequence is outputted from the wave formatter 79 to thereby direct the memory device 19′ to output a serial data from a memory location. The outputted serial data from the memory device 19′ is then compared to the pattern signal in the pattern comparator 81. If the address being tested fails the test (e.g., the read serial data is different than an expected or original data), then the failed address is stored in the fail memory 84 for further processing.

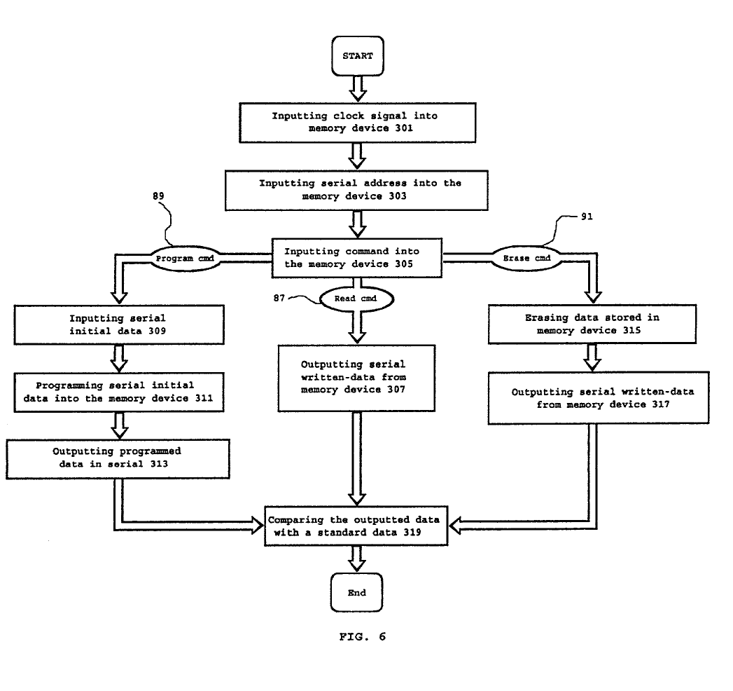

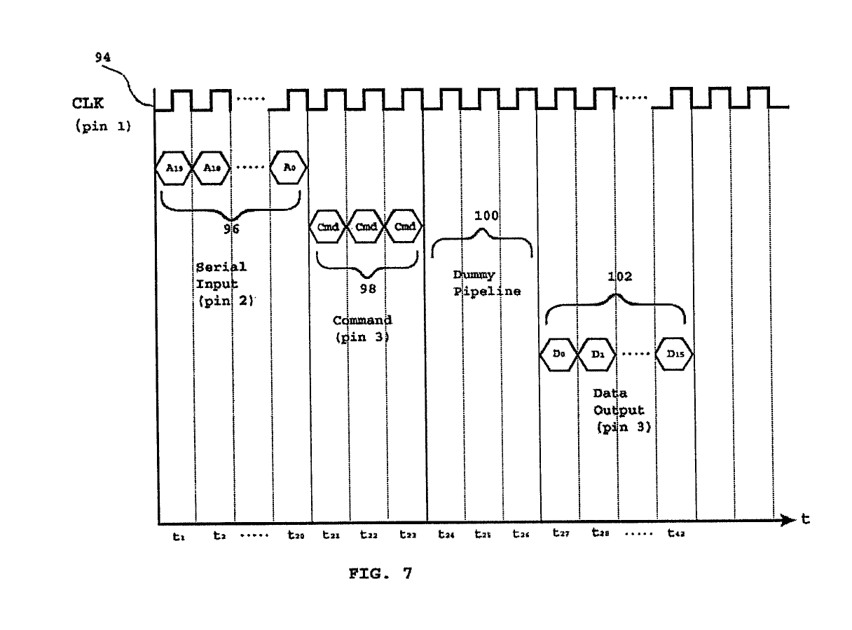

Turning now to FIG. 6, a flow chart is provided setting forth steps for testing a single memory device in accordance with an embodiment of the present invention. The method, which may be performed, for example, by the serial I/O testing system 42 of FIG. 3a, begins at Step 301 by inputting a clock signal from the clock probe 47 into the memory device through the first pin 32, that pin 32 being a clock input pin. As shown in FIG. 7, which is a diagram showing a timing sequence for a “read” command test of a single memory device as implemented by a serial I/O testing system 42, the clock signal 94 is used for synchronization.

At Step 303 a serial address is inputted from the address probe 49 into the memory device 19′ through the second pin 34, which is an address pin. Referring again to FIG. 7, the serial address is synchronized with the clock signal 94. In the present example the serial address includes twenty address bits (A19, A18, . . . , A0) corresponding to twenty clock cycles, each cycle lasting 50 ns; but these values may be changed in modified embodiments. The twenty cycles will hereinafter be referred to as serial input cycles 96. Every time the clock signal 94 goes high (logical value switches from 0 to 1) an address bit is inputted. In inputting signals whenever the clock signal 94 goes high, a clock cycle is broken down into a raising time and a holding time. The raising time corresponds to the period before the clock signal 94 is high, and the holding time is the period after the clock signal 94 is high. Here, the period of each address bit includes a rising time and a holding time. Thus, one can confirm that the address signals are input in synchronization with the cycles of the clock.

Since it is known to those having skill in this art that it is equally possible to input signals when the clock signal 94 goes low (logical value switches from a 1 to a 0), this implementation and possibly other modifications are considered to be within the scope of the present invention. Synchronization with the rising clock signal for inputting, as well as outputting, is provided only as an exemplary embodiment, and should therefore not be construed as a limitation. Other signals or data, which are inputted or outputted as described herein, synchronized with the clock signal, operate and are timed with the clock signal functionally equivalently as described with respect to the serial address input.

The present example includes twenty address bits which allow for 2\hat{ }20 addresses. In a conventional testing system, each address bit will typically correspond to a single address pin. Consequently, for a twenty bit address, twenty pins will typically be required. In accordance with the present invention, however, the number of address pins required for the same twenty bit address, or for any address, during testing is reduced to one. In the illustrated embodiment, a single clock cycle should still be consumed for each address bit.

A command is input from the serial I/O testing system 42 into the memory device 19′ at Step 305. As presently embodied, the command may be input from the I/O probe 51 of the serial I/O testing system 42 into the third pin 36 (which is an I/O pin) of the memory device 19′. In the presently described method the three possible commands include a read command 87, a program command 89, and an erase command 91. When the read command 87 is executed, the method proceeds to Step 307. Should the program command 89 be executed, the method proceeds to Step 309; and if the erase command 91 is executed, the method proceeds to Step 315.

Since the command, the data input, and the data output signals all share the third pin 36 in the illustrated embodiment, the various operations are preferably distributed over time. Referring once again to FIG. 7, the clock cycles t₂₁ through t₂₃ are used to determine which command is to be executed. Each command is synchronized with the clock signal and corresponds to a particular clock cycle position. For example, if clock cycle t₂₁ corresponded to the read command 87, then if at time t₂₁ the third pin 36 received an “on” value (logical 1), then the command to be executed would be the read command 87 and the method would continue on to Step 307. The three clock cycles used to issue the command will henceforth be referred to as command cycles 98.

After the read command 87 is issued, three clock cycles are used for what is referred to as dummy cycles or a dummy pipeline 100. A dummy cycle or cycles is a signal containing no data that is issued into the pipeline. The dummy cycles 100 are used for purposes of synchronization. Without the dummy cycles 100 the signals would fall out of sync with the clock cycles and the serial I/O testing system 42 may cease to be able to communicate with the memory device 19′.

When the command that has been executed is the read command 87, data in the memory device 19′ is accessed according to the address A19, A18, . . . , A0 bits that were input into the second pin 34 during the serial input cycles 96. The data, which typically will contain data that was previously written (programmed) into the memory device 19′ in a serial fashion in synchronization with the clock signal 94, is then output through the third pin 36 to the serial I/O testing system 42. This outputting process is shown in FIG. 7, wherein the data is outputted synchronizing with the clock signal 94. In the present example this data output is a is sixteen bit value (D0, D1, . . . , D15), so that sixteen clock cycles are used to output the value from the memory device 19′. From here forth, these clock cycles will be referred to as data output cycles 102.

As can be discerned from FIGS. 6 and 7 the entire read process for the present example, from the entering of the address (Step 303) to the outputting of the memory contents (Step 307) requires forty-two clock cycles, including twenty serial input cycles 96, three command cycles 98, three dummy cycles 100, and sixteen data output cycles 102.

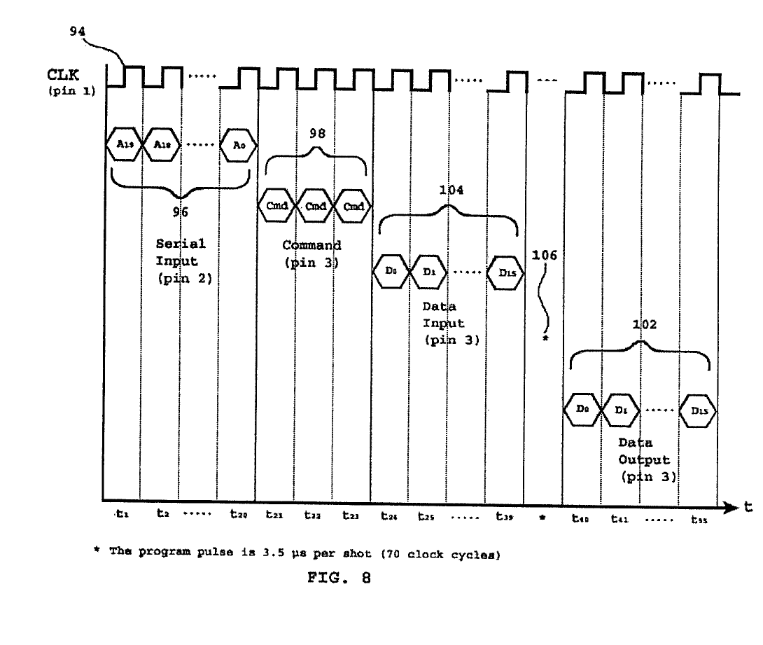

With continuing reference to FIG. 6, when the program command 89 is selected, initial data is serially input into the memory device 19′ through the third pin 36 at Step 309. The serial initial data is input in synchronization with the clock signal 94 as shown in FIG. 8. Since in the illustrated example the data is sixteen bit, sixteen clock cycles are used to input the data. These cycles, which are illustrated in FIG. 8, will be referred to as data input cycles 104. After the serial initial data is input it is then programmed into the memory device (Step 311). This process is accomplished using a series of program pulses. During each program pulse, which in the illustrated example consumes 3.5 microseconds or seventy clock cycles, a data polling mode 106 is entered on the memory device 19′. In the data polling mode 106 the memory locations being programmed, which correspond to the address A19, A18, . . . , A0 bits that were input into the second pin 34 during the serial input cycles 96 of the memory device 19′, are monitored for a polling bit signal. This signal shows when the memory locations have swithed from their initial value (1 or 0) to their final value (0 or 1). When this switch occurs, the polling bit signal is output to the serial I/O testing system 42 through the third pin 36 in synchronization with the clock. Ten program pulses are required in the illustrated example to switch a memory value from 0 to 1 or from 1 to 0. Sixteen clock cycles are consumed by the polling bit signal, one clock cycle for each data bit which has been written. The memory location is thus programmed with the serial initial data and verified.

The program process in the present example thus requires a total of fifty-five clock cycles, including twenty serial input cycles 96, three command cycles 98, sixteen data input cycles 104, and sixteen data output cycles for the polling bit signals. Thirty-five microseconds are also normally used up in the actual programming of the memory device as a result of the ten programming pulses. Thus, the process of the described embodiment in actuality takes 755 clock cycles.

At Step 315, upon receipt of the erase command 91, data stored in a memory location corresponding to the address received on the second pin 34 of the memory device 19′ is erased. The time required to erase the memory location of the memory device 19′ and the method of doing so is substantially similar to the program command. As for one difference, during the data input cycles 104 an empty value may be inputted. Once the memory contents have been erased they are output (Step 317) through the third pin 36 in synchronization with the clock signal, in a fashion similar to the polling bit signal 106 of the programming mode.

Step 319 follows Steps 307, 313, and 317. In Step 319 the outputted data is compared with a standard data stored in the serial I/O testing system 42 for such purposes. For example, when a read command 87 is executed in Step 307, the outputted data, which preferably comprises a serially-written data, is compared with an original data stored in the serial I/O testing system 42 onboard memory (e.g., in the pattern comparator 81) so as to confirm that the read procedure is correct and that the memory address previously written to and now read from is not defective. As another example, after the program command 89 is executed in Steps 309 to 313, the outputted data, which should correspond to the serial initial data, is compared with a serial initial data reference stored in the serial I/O testing system 42 onboard memory so as to confirm that the memory address written to is not defective. When the erase command 91 is executed in Steps 315 and 317, the outputted data, which should be serially-written data and more particularly data having an erased status, is compared with a standard data in order to determine whether or not the contents of the memory address have been erased.

As described above, the memory device 19′ may also contain a write enable, a chip enable, and an output enable pin as shown in FIGS. 2 and 3. Thus, the serial I/O testing method may further include steps of asserting a write enable signal to the memory device 19′ through the fourth pin 26, a chip enable signal through the fifth pin 28, and an output enable signal through the sixth pin 30 of the memory device.

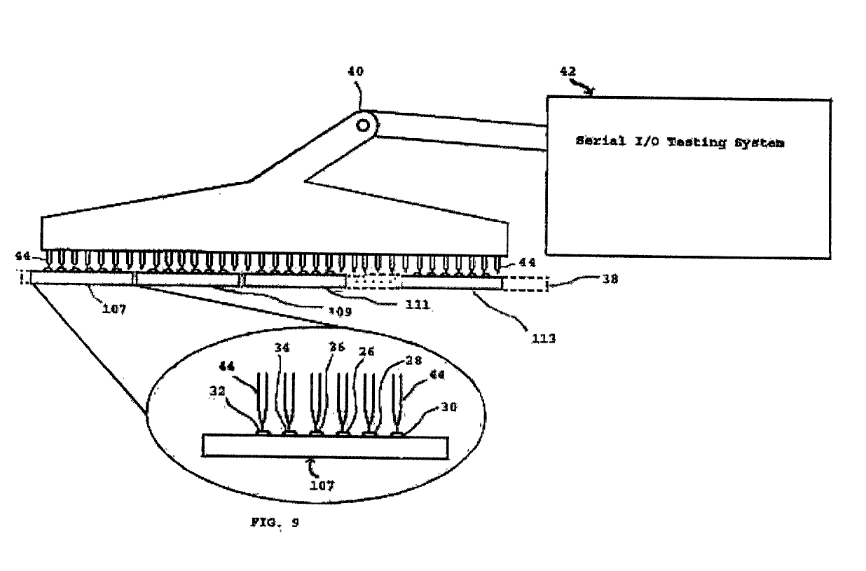

As an alternative embodiment, the aforementioned serial I/O testing system may be implemented to test a plurality of memory devices simultaneously. FIG. 9 shows a serial I/O testing system 42 in contact with a first memory device 107, a second memory device 109, a third memory device 111, through an nth memory device 113 by a plurality of probes 44. Each memory device may have a first pad 32, a second pad 34, a third pad 36, and optionally a fourth pad 26, a fifth pad 28, and a sixth pad 30, and may be constructed similarly to the memory devices 19′ and 19″ described above. The memory devices are tested in parallel and therefore it takes no longer to test eight memory devices than to test one memory device. Since each memory device contains three (or, for example, two or six) pads, a testing system containing 48 probes is capable of testing at least eight memory devices at once in parallel. Greater or fewer numbers of probes can be implemented to test simultaneously greater or fewer numbers of memory devices.

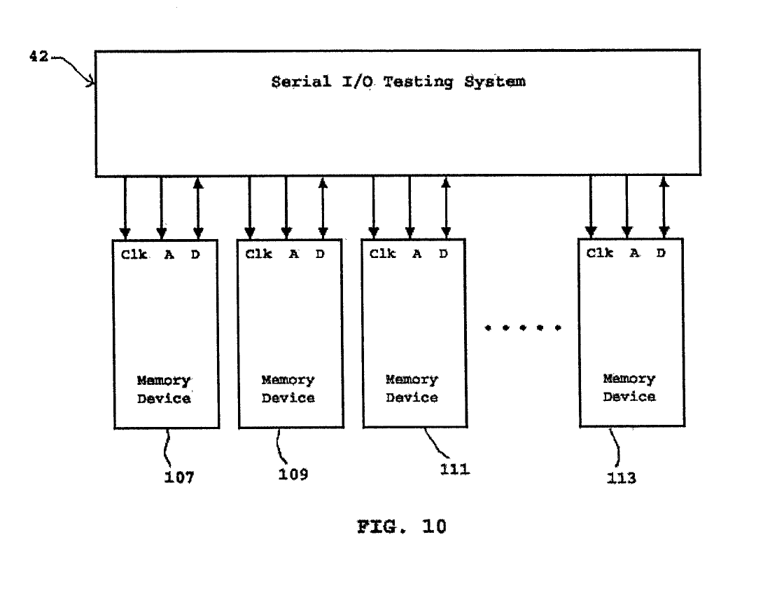

FIG. 10 depicts the serial I/O testing system 42 connected to a first memory device 107, a second memory device 109, a third memory device 111, through an nth memory device 113, with the difference from FIG. 9 being that the memory devices are in their packaged form in this figure. Therefore the contact points are pins as opposed to pads. The memory devices are constructed and operate similarly to the memory devices 19′ and 19″ described above with reference to FIGS. 2-8.

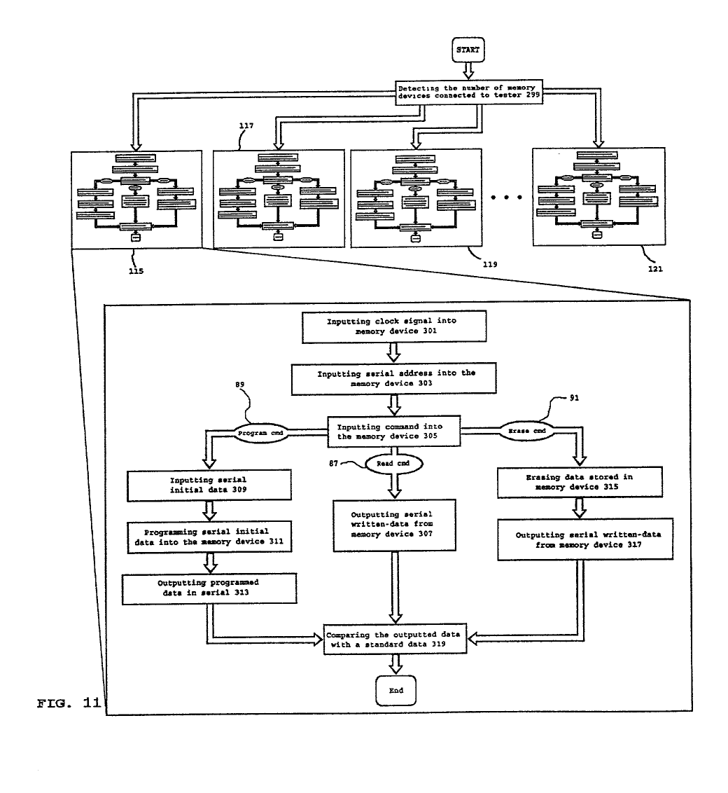

A serial I/O testing method for testing a plurality of memory devices in parallel is shown in FIG. 11. The method for testing a plurality of memory devices begins with Step 299 in which the serial I/O testing system 42 detects the number of memory devices to which it is connected. In the illustrated embodiment the serial I/O testing system 42 is connected to n memory devices. In one embodiment, n is equal to eight. When n memory devices are detected, the serial I/O testing system 42 then begins Step 300 in which it may query each attached memory device and wait until all devices are synchronized with one another before advancing the clock signal. In a modified embodiment, Step 300 may encompass the serial I/O testing system 42 synchronizing with the attached memory devices by synchronizing the timing of signals, such as the clock, address, command and/or polling signal actions among the attached memory devices. The testing system then simultaneously continues the process flow of the first device 115, the process flow of the second device 117, the process flow of the third device 119, through the process flow of the nth device 121. The individual testing procedure for each memory device is the same as described above.

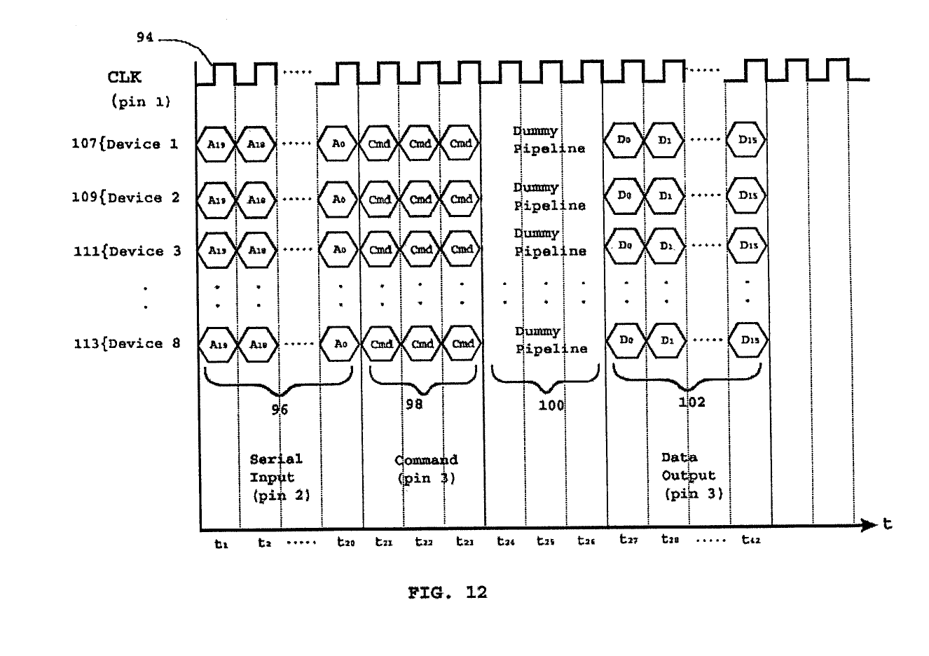

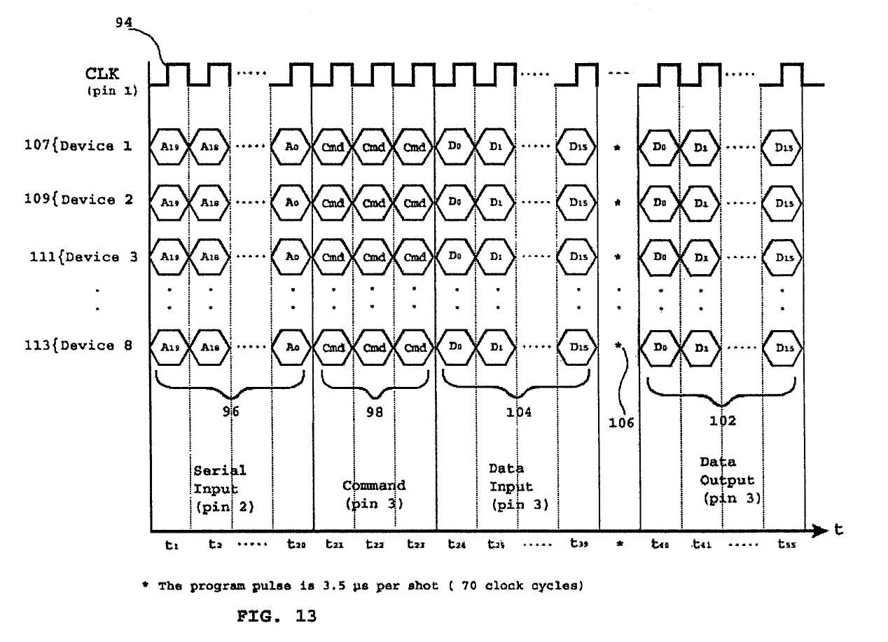

The timing diagram of FIG. 12 depicts the read command of the present invention's testing method for simultaneously testing a plurality of memory devices. Tested in parallel are a first memory device 107, a second memory device 109, a third memory device 111, through an nth memory device 113, where n in the illustrated embodiment is equal to eight. As shown, the serial input cycles 96, command cycles 98, dummy cycles 100, and polling bit signals 106 preferably occur simultaneously for each memory device 19′. FIG. 13 similarly sets forth a timing diagram depicting the program command of the present invention's testing method as simultaneously applied on a plurality of memory devices 19′. In the program and erase modes of operation, the serial I/O testing system 42 preferably waits until all of the memory devices have received the polling bit signal before proceeding to Step 319. Once all of the memory devices have forwarded the necessary polling bit signal in accordance with a preferred embodiment, they enter Step 319 in unison.

It is known to those having skill in the art of memory testing that the testing time for a read procedure of a conventional testing device is about 300 ns per device under test (DUT). The testing time when using the present invention is forty-two clock cycles for a DUT as discussed above, and at 50 ns per clock signal the testing time equates to 2100 ns for a single device. Now, when eight memory devices are tested in parallel with the present invention (using 48 pins), the testing time is still 2100 ns, so that the testing time per DUT is one-eighth of 2100 ns or 262.5 ns per DUT. For a conventional parallel I/O tester to test eight devices using the same number (e.g., forty-eight) or a similar number (e.g., forty-two) of probes it would take 2400 ns, since the eight memory device would have to be tested one at a time. If the conventional tester were equipped with eight times more pins, it could indeed test all eight memory devices at once for a testing time of 300 ns per DUT. However, if the memory testing system of the present invention were also equipped with eight times the number of pins, or three hundred eighty-four pins, then it could test sixty-four devices at once for a testing time of 32.8 ns per DUT compared to 300 ns per DUT for the prior art tester having a comparable number of pins.

Furthermore, it is known to those having skill in the art of memory testing that the testing time for a program procedure using a conventional tester is the sum of 500 ns per device (for the programming process) and 35 us (for the actual programming as a result of the ten programming pulses as discussed above), for a total of 35.5 us per device under test (DUT). The testing time when using the present invention for a program procedure is about seven hundred fifty-five clock cycles for a DUT as discussed above, and at 50 ns per clock signal the time equates to 37.75 us per DUT. Now, when eight memory devices are tested in parallel with the present invention (using 48 pins), the testing time is still 37.75 us, so that the testing time per DUT is one-eighth of that or 4.72 us per DUT. For a conventional parallel I/O tester to test eight devices using the same number (e.g., forty-eight) or a similar number (e.g., forty-two) of probes it would take 284 us, since the eight memory devices would have to be tested one at a time. If the conventional tester were equipped with eight times more pins, it could test all eight memory devices at once for a testing time of 35.5 us per DUT. However, if the memory testing system of the present invention were also provided eight times the number of pins, or three hundred eighty-four pins, then it could test sixty-four devices at once for a testing time of 0.59 us per DUT compared to 35.5 us per DUT for the prior art tester having a comparable number of pins. Thus, a substantial increase in testing time is realized with the present invention.

In view of the foregoing, it will be understood by those skilled in the art that the methods of the present invention can facilitate the efficient testing of memory devices using serial I/O communications and synchronization of inputs and outputs with a timing signal. The above-described embodiments have been provided by way of example, and the present invention is not limited to these examples. Multiple variations and modification to the disclosed embodiments will occur, to the extent not mutually exclusive, to those skilled in the art upon consideration of the foregoing description. For example, the serial I/O testing system may have more than one physical site for testing memory devices, wherein, for instance, the serial I/O testing system has four sites with each site comprising forty-eight probes to thereby facilitate the testing of thirty-two memory devices at the same time. Such variations and modifications to the description of the invention described herein, however, fall well within the scope of the present invention as set forth in the following claims.

What is claimed is:

1. A serial I/O testing method performed by a testing system for testing a memory device, the memory device having a first pin and at least one additional pin, the testing method comprising the following steps:
inputting a clock into the memory device through the first pin;
inputting a serial address into the memory device through the at least one additional pin,
wherein the serial address is inputted synchronized with the clock;
inputting a command into the memory device; and
when the command is a read command, outputting from the at least one additional pin synchronized with the clock a serially-written data, wherein the serially-written data corresponds to serially-written data stored in the memory device.
and a third pin

2. The testing method as set forth in claim 1, wherein:
the at least one additional pin is a second pin; and
the method further comprises a step of comparing the serially-written data and an original data.

3. The testing method as set forth in claim 1, further comprising the following steps:
when the command is a program command, serially inputting an initial data through the at least one additional pin, wherein the initial data is synchronized with the clock;
programming the initial data into the memory device; and
outputting the programmed initial data in serial from the memory device through the at least one additional pin, wherein the programmed initial data is outputted synchronized with the clock.

4. The testing method as set forth in claim 3, further comprising a step of comparing the programmed initial data and an original data.

5. The testing method as set forth in claim 1, further comprising the following steps:
when the command is an erase command, erasing data stored in the memory device; and
outputting a serially-written data from the memory device through the at least one additional pin, wherein the serially-written data corresponds to serially-written data stored in the memory device which should be erased as a result of the erase command.

6. The testing method as set forth in claim 5, wherein
the at least one additional pin comprises a first pin and a second pin;
the serial address is inputted through the second pin;
the serial written data is outputted through the third pin; and
the testing method further comprises a step of analyzing the serially-written data.

7. The testing method as set forth in claim 6, wherein the memory device further comprises a fourth pin, a fifth pin, and a sixth pin, and the method further comprises the following steps:
inputting a chip-enable signal to the memory device through the fourth pin;
inputting an output-enable signal to the memory device through the fifth pin; and
inputting a write-enable signal to the memory device through the sixth pin.

8. A testing method comprising the following steps:
providing a memory device and a timing signal;
serially inputting an address into the memory device, wherein the address is inputted in synchronization with the timing signal;
inputting a command into the memory device;
interpreting the command;
accessing a memory location of the memory device using the address, upon an interpretation of the command as a read command; and
outputting data from the memory location in synchronization with the timing signal, upon an interpretation of the command as a read command.

9. The testing method as set forth in claim 8, wherein the step of outputting data from the memory location comprises a step of serially outputting data from the memory location in synchronization with the timing signal.

10. The testing method as set forth in claim 9, wherein the step of providing a memory device and a timing signal is followed by a step of inputting the timing signal into the memory device.

11. The testing method as set forth in claim 10, wherein the step of inputting the timing signal comprises a step of inputting a clock signal from the testing system into the memory device.

12. The testing method as set forth in claim 11, wherein the step of serially outputting data from the memory location comprises a step of serially outputting from the memory location data that was previously serially-written into the memory location.

13. The testing method as set forth in claim 12, further comprising a step of comparing the serially outputted data and an original data.

14. The testing method as set forth in claim 12, wherein:
the step of providing a memory device comprises a step of providing a memory device comprising a first input, a second input, and a third input/output;
the clock signal is inputted into the memory device through the first input;
the address is inputted into the memory device through the second input; and
the data is outputted from the memory device through the third input/output.

15. The testing method as set forth in claim 14, the step of providing a memory device comprises a step of providing a memory device comprising one of an OPT ROM, a MTP ROM, an EPROM, and a Flash.

16. The testing method as set forth in claim 14, wherein the step of inputting a command into the memory device comprises a step of inputting a command into the memory device through the third input/output.

17. The testing method as set forth in claim 14, wherein upon an interpretation that the command is a program command the step of interpreting the command is followed by the below steps:
serially inputting initial data into the memory device in synchronization with the clock signal;
programming the initial data into a memory location of the memory device, the memory location corresponding to the address;
accessing the memory location using the address; and
outputting data from the memory location in synchronization with the clock signal.

18. The testing method as set forth in claim 17, further comprising a step of comparing the outputted data and an original data.

19. The testing method as set forth in claim 14, wherein upon an interpretation that the command is an erase command the step of interpreting the command is followed by the below steps:
erasing data in a memory location of the memory device, the memory location corresponding to the address;
accessing the memory location using the address; and
outputting data from the memory location in synchronization with the clock signal.

20. The testing method as set forth in claim 19, further comprising a step of analyzing the outputted data from the memory location.

21. The testing method as set forth in claim 14, wherein the memory device further comprises a fourth input, a fifth input, and a sixth input, and the method further comprises the following steps:
inputting a chip-enable signal to the memory device through the fourth input;
inputting a output-enable signal to the memory device through the fifth input; and
inputting a write-enable signal to the memory device through the sixth input.

22. A serial I/O testing method performed in a testing system for testing a memory device, the method comprising the following steps:
inputting a timing signal from the testing system into the memory device;
inputting an address serially into the memory device, the address being inputted into the memory device from the testing system in synchronization with the timing signal;
accessing a memory location of the memory device using the address; and
outputting data serially from the memory location in synchronization with the timing signal.

23. The serial I/O testing method as set forth in claim 22, further comprising a step of inputting a command into the memory device.

24. The serial I/O testing method as set forth in claim 23, wherein:
the accessing step and the outputting step are performed when the command is a read command;
the data outputted in the outputting step comprises serially-written data, when the command is a read command; and
the method further comprises a step of comparing the serially-written data and an original data, when the command is a read command.

25. The testing method as set forth in claim 23, wherein:
when the command is a program command the accessing step is proceeded by the following steps:
(a) serially inputting initial data into the memory device in synchronization with the timing signal; and
(b) programming the initial data into the memory location of the memory device; and the method further comprises a step of comparing the outputted data and an original data.

26. A parallel memory device comprising a plurality of I/O pins which are constructed to facilitate parallel communications between the parallel memory device and an external device during a standard operating mode of the memory device, wherein in a testing mode one pin of the parallel memory device is constructed to input a clock signal and at least one other pin of the parallel memory device is constructed to perform serial I/O operations with an external memory testing device in synchronization with the clock signal.

27. The parallel memory device as set forth in claim 26, wherein the at least one other pin is constructed to serially input address signals in synchronization with the clock signal in the testing mode.

28. The parallel memory device as set forth in claim 27, wherein the at least one other pin is further constructed to serially output data signals in synchronization with the clock signal in the testing mode, the data signals corresponding to data stored in memory cells of the parallel memory device which are indexed by the serially input address signals.

29. The parallel memory device as set forth in claim 28, wherein the plurality of I/O pins includes the one pin and the at least one other pin.

30. The parallel memory device as set forth in claim 28, wherein the at least one other pin comprises:
a pin constructed to serially input the address data in the testing mode in synchronization with the clock signal; and
a pin constructed to serially output the data signals in the testing mode in synchronization with the clock.

31. The parallel memory device as set forth in claim 30, wherein the plurality of I/O pins includes the one pin and the at least one othe pin.
